(19) United States
(12) Patent Application Publication
(10) Pub. No.: US 2013/0326297 A1
(43) Pub. Date: Dec. 5, 2013

(54) SEMICONDUCTOR APPARATUS

(71) Applicant: In Jun MOON, Gyeonggi-do (KR)

(72) Inventor: In Jun MOON, Gyeonggi-do (KR)

(73) Assignee: SK HYNIX INC., Icheon-si (KR)

(21) Appl. No.: 13/602,265

(22) Filed: Sep. 3, 2012

(30) Foreign Application Priority Data
May 31, 2012 (KR) 10-2012-0058226

(51) Int. Cl. G01R 31/3177

(52) U.S. Cl. CPC G01R 31/3177
USPC 714/724

(57) ABSTRACT

A semiconductor apparatus includes a control signal generation unit configured to generate a control signal in response to a set signal, a test signal and a test reset signal; a first test selection unit configured to generate a first test mode signal in response to a first select signal and the control signal; a second test selection unit configured to generate a second test mode signal in response to a second select signal and the control signal; and a test reset signal generation unit configured to output the second test mode signal as the test reset signal.

### CROSS-REFERENCES TO RELATED APPLICATION

The present application claims priority under 35 U.S.C. §119(a) to Korean application number 10-2012-0058226, filed on May 31, 2012, in the Korean Intellectual Property Office, which is incorporated herein by reference in its entirety.

### BACKGROUND

1. Technical Field

The present invention relates to a semiconductor integrated circuit, and more particularly, to a semiconductor apparatus.

2. Related Art

In general, in a semiconductor apparatus, tests are performed to determine whether the semiconductor apparatus is good or defective.

Therefore, various kinds of tests for testing whether the semiconductor apparatus is good or defective are performed for the semiconductor apparatus.

Referring to FIG. 1, a conventional semiconductor apparatus includes a reset signal generation unit 10, a control signal generation unit 20, and first to fifth test selection units 31 to 35, which are configured such that various kinds of tests can be performed.

The reset signal generation unit 10 enables a test mode reset signal TM_reset when a first reset signal Reset_{—}1 is enabled, and disables the test mode reset signal TM_reset when a second reset signal Reset_{—}2 is enabled.

The control signal generation unit 20 enables a control signal ctrl when a test signal Test and a set signal SET are enabled, and disables the control signal ctrl when the test mode reset signal TM_reset is enabled.

The first test selection unit 31 generates a first test mode signal TM1 in response to a first select signal sel_{—}1 when the control signal ctrl is enabled. For example, the first test selection unit 31 enables the first test mode signal TM1 when the control signal ctrl and the first select signal sel_{—}1 are enabled. Also, the first test selection unit 31 disables the first test mode signal TM1 when the control signal ctrl is enabled and the first select signal sel_{—}1 is disabled. The first test selection unit 31 disables the first test mode signal TM1 regardless of the first select signal sel_{—}1 when the control signal ctrl is disabled.

The second test selection unit 32 generates a second test mode signal TM2 in response to a second select signal sel_{—}2 when the control signal ctrl is enabled. For example, the second test selection unit 32 enables the second test mode signal TM2 when the control signal ctrl and the second select signal sel_{—}2 are enabled. Also, the second test selection unit 32 disables the second test mode signal TM2 when the control signal ctrl is enabled and the second select signal sel_{—}2 is disabled. The second test selection unit 32 disables the second test mode signal TM2 regardless of the second select signal sel_{—}2 when the control signal ctrl is disabled.

The third test selection unit 33 generates a third test mode signal TM3 in response to a third select signal sel_{—}3 when the control signal ctrl is enabled. For example, the third test selection unit 33 enables the third test mode signal TM3 when the control signal ctrl and the third select signal sel_{—}3 are enabled. Also, the third test selection unit 33 disables the third test mode signal TM3 when the control signal ctrl is enabled and the third select signal sel_{—}3 is disabled. The third test selection unit 33 disables the third test mode signal TM3 regardless of the third select signal sel_{—}3 when the control signal ctrl is disabled.

The fourth test selection unit 34 generates a fourth test mode signal TM4 in response to a fourth select signal sel_{—}4 when the control signal ctrl is enabled. For example, the fourth test selection unit 34 enables the fourth test mode signal TM4 when the control signal ctrl and the fourth select signal sel_{—}4 are enabled. Also, the fourth test selection unit 34 disables the fourth test mode signal TM4 when the control signal ctrl is enabled and the fourth select signal sel_{—}4 is disabled. The fourth test selection unit 34 disables the fourth test mode signal TM4 regardless of the fourth select signal sel_{—}4 when the control signal ctrl is disabled.

The fifth test selection unit 35 generates a fifth test mode signal TM5 in response to a fifth select signal sel_{—}5 when the control signal ctrl is enabled. For example, the fifth test selection unit 35 enables the fifth test mode signal TM5 when the control signal ctrl and the fifth select signal sel_{—}5 are enabled. Also, the fifth test selection unit 35 disables the fifth test mode signal TM5 when the control signal ctrl is enabled and the fifth select signal sel_{—}5 is disabled. The fifth test selection unit 35 disables the fifth test mode signal TM5 regardless of the fifth select signal sel_{—}5 when the control signal ctrl is disabled.

The conventional semiconductor apparatus configured in this way operates as follows.

When starting a test, the control signal generation unit 20 receives the test signal Test and the set signal SET which are enabled, and enables the control signal ctrl.

The enabled control signal ctrl is inputted to the first to fifth test selection units 31 to 35. The first to fifth test selection units 31 to 35, which receive the enabled control signal ctrl, selectively enable the first to fifth test mode signals TM1 to TM5 in response to the respectively corresponding first to fifth select signals sel_{—}1 to sel_{—}5.

When ending the test, the reset signal generation unit 10 receives the first reset signal Reset_{—}1 which is enabled, and enables the test mode reset signal TM_reset.

The control signal generation unit 20 receives the enabled test mode reset signal TM_reset and disables the control signal ctrl.

If the control signal ctrl is disabled, the first to fifth test selection units 31 to 35 disable the first to fifth test mode signals TM1 to TM5.

Then, the reset signal generation unit 10 receives the second reset signal Reset_{—}2 which is enabled, and disables the test mode reset signal TM_reset.

As described above, in the conventional semiconductor apparatus, when ending the test, the first reset signal Reset_{—}1 should be received for enabling the test mode reset signal TM_reset in order to disable all of the plurality of test selection units 31 to 35. Also, the second reset signal Reset_{—}2 should be received to disable the test mode reset signal TM_reset which is enabled by the first reset signal Reset_{—}1. The two reset signals Reset_{—}1 and Reset_{—}2 are signals which are inputted from outside of the semiconductor apparatus, that is, inputted from test equipment.

Therefore, a technology capable of decreasing the number of signal lines connected between the test equipment and the semiconductor apparatus and thereby testing an increased number of semiconductor apparatuses at once is demanded.

### SUMMARY

In one embodiment of the present invention, a semiconductor apparatus includes: a control signal generation unit configured to generate a control signal in response to a set signal, a test signal and a test reset signal; a first test selection unit configured to generate a first test mode signal in response to a first select signal and the control signal; a second test selection unit configured to generate a second test mode signal in response to a second select signal and the control signal; and a test reset signal generation unit configured to output the second test mode signal as the test reset signal.

In another embodiment of the present invention, a semiconductor apparatus includes: a first group test mode signal generation block configured to generate a plurality of first group test mode signals in response to a set signal, a test signal and a plurality of first group select signals, and disable the plurality of first group test mode signals in response to any one of the plurality of first group select signals; and a second group test mode signal generation block configured to generate a plurality of second group test mode signals in response to the set signal, the test signal and a plurality of second group select signals, and disable the plurality of second group test mode signals in response to any one of the plurality of second group select signals.

### BRIEF DESCRIPTION OF THE DRAWINGS

Features, aspects, and embodiments are described in conjunction with the attached drawings, in which:

FIG. 1 is a configuration diagram of a conventional semiconductor apparatus;

FIG. 2 is a configuration diagram of a semiconductor apparatus in accordance with an embodiment of the present invention;

FIG. 3 is a configuration diagram of a test reset signal generation unit of FIG. 2;

FIG. 4 is a configuration diagram of a semiconductor apparatus in accordance with another embodiment of the present invention; and

FIG. 5 is a configuration diagram of a first group test reset signal generation unit of FIG. 4.

### DETAILED DESCRIPTION

Hereinafter, a semiconductor apparatus according to the present invention will be described below with reference to the accompanying drawings through example embodiments.

Referring to FIG. 2, a semiconductor apparatus in accordance with an embodiment of the present invention includes a control signal generation unit 100, first to fifth test selection units 210 to 250, and a test reset signal generation unit 300.

The control signal generation unit 100 is configured to generate a control signal ctrl in response to a set signal SET, a test signal Test and a test reset signal TM_reset. For example, the control signal generation unit 100 enables the control signal ctrl when the test signal Test and the set signal SET are enabled, and disables the control signal ctrl when the test reset signal TM_reset is enabled.

The first test selection unit 210 is configured to generate a first test mode signal TM1 in response to a first select signal sel_{—}1 and the control signal ctrl. For example, the first test selection unit 210 generates the first test mode signal TM1 in response to the first select signal sel_{—}1 when the control signal ctrl is enabled, and disables the first test mode signal TM1 regardless of the state of the first select signal sel_{—}1 when the control signal ctrl is disabled, that is regardless of whether the first select signal sel_{—}1 is enabled or disabled. Further, the first test selection unit 210 enables the first test mode signal TM1 when the control signal ctrl is enabled and the first select signal sel_{—}1 is enabled, and disables the first test mode signal TM1 when the control signal ctrl is enabled and the first select signal sel_{—}1 is disabled.

The second test selection unit 220 is configured to generate a second test mode signal TM2 in response to a second select signal sel_{—}2 and the control signal ctrl. For example, the second test selection unit 220 generates the second test mode signal TM2 in response to the second select signal sel_{—}2 when the control signal ctrl is enabled, and disables the second test mode signal TM2 regardless of the state of the second select signal sel_{—}2 when the control signal ctrl is disabled. Further, the second test selection unit 220 enables the second test mode signal TM2 when the control signal ctrl is enabled and the second select signal sel_{—}2 is enabled, and disables the second test mode signal TM2 when the control signal ctrl is enabled and the second select signal sel_{—}2 is disabled.

The third test selection unit 230 is configured to generate a third test mode signal TM3 in response to a third select signal sel_{—}3 and the control signal ctrl. For example, the third test selection unit 230 generates the third test mode signal TM3 in response to the third select signal sel_{—}3 when the control signal ctrl is enabled, and disables the third test mode signal TM3 regardless of the state of the third select signal sel_{—}3 when the control signal ctrl is disabled. Further, the third test selection unit 230 enables the third test mode signal TM3 when the control signal ctrl is enabled and the third select signal sel_{—}3 is enabled, and disables the third test mode signal TM3 when the control signal ctrl is enabled and the third select signal sel_{—}3 is disabled.

The fourth test selection unit 240 is configured to generate a fourth test mode signal TM4 in response to a fourth select signal sel_{—}4 and the control signal ctrl. For example, the fourth test selection unit 240 generates the fourth test mode signal TM4 in response to the fourth select signal sel_{—}4 when the control signal ctrl is enabled, and disables the fourth test mode signal TM4 regardless of the state of the fourth select signal sel_{—}4 when the control signal ctrl is disabled. Further, the fourth test selection unit 240 enables the fourth test mode signal TM4 when the control signal ctrl is enabled and the fourth select signal sel_{—}4 is enabled, and disables the fourth test mode signal TM4 when the control signal ctrl is enabled and the fourth select signal sel_{—}4 is disabled.

The fifth test selection unit 250 is configured to generate a fifth test mode signal TM5 in response to a fifth select signal sel_{—}5 and the control signal ctrl. For example, the fifth test selection unit 250 generates the fifth test mode signal TM5 in response to the fifth select signal sel_{—}5 when the control signal ctrl is enabled, and disables the fifth test mode signal TM5 regardless of the state of the fifth select signal sel_{—}5 when the control signal ctrl is disabled. Further, the fifth test selection unit 250 enables the fifth test mode signal TM5 when the control signal ctrl is enabled and the fifth select signal sel_{—}5 is enabled, and disables the fifth test mode signal TM5 when the control signal ctrl is enabled and the fifth select signal sel_{—}5 is disabled.

The test reset signal generation unit 300 is configured to output the fifth test mode signal TM5 as the test reset signal TM_reset. For example, the test reset signal generation unit 300 enables the test reset signal TM_reset when the fifth test mode signal TM5 is enabled, and disables the test reset signal TM_reset when the fifth test mode signal TM5 is disabled.

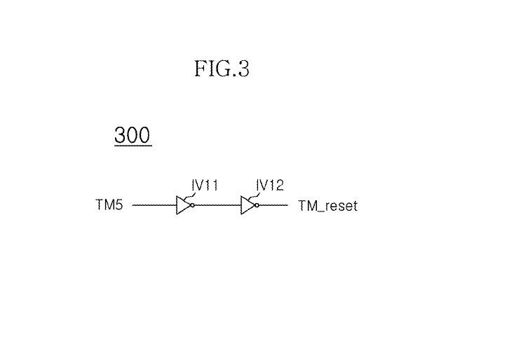

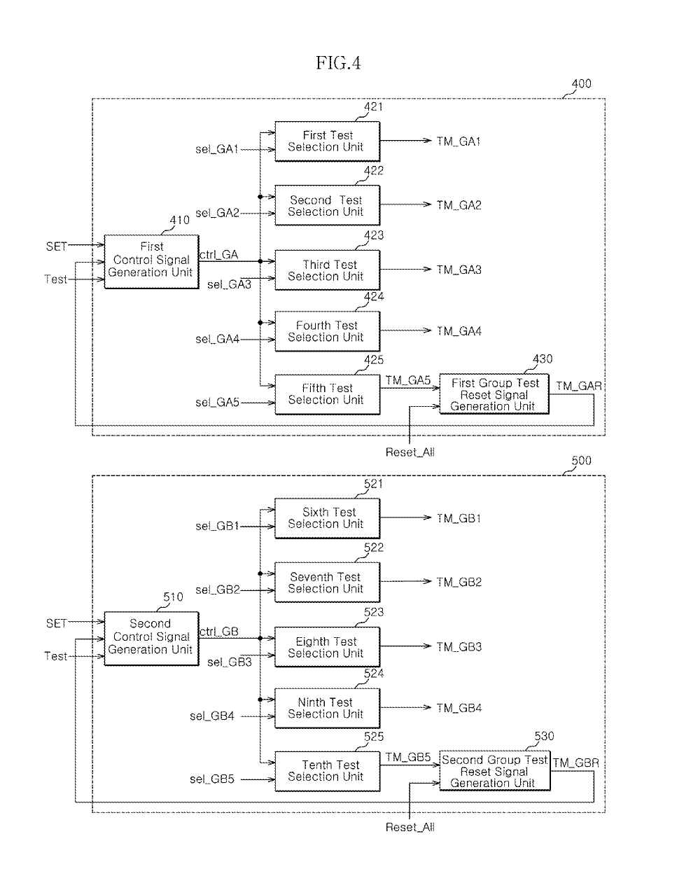

Referring to FIG. 3, the test reset signal generation unit 300 includes first and second inverters IV11 and IV12. The first inverter IV11 receives the fifth test mode signal TM5. The second inverter IV12 receives the output signal of the first inverter IV11 and outputs the test reset signal TM_reset.

The semiconductor apparatus in accordance with an embodiment of the present invention, configured as mentioned above, operates as follows.

When performing a test, the control signal generation unit 100 enables the control signal ctrl when the test signal Test is enabled and the set signal SET is enabled.

When the control signal ctrl is enabled, the first test selection unit 210 generates the first test mode signal TM1 in response to the first select signal sel_{—}1.

When the control signal ctrl is enabled, the second test selection unit 220 generates the second test mode signal TM2 in response to the second select signal sel_{—}2.

When the control signal ctrl is enabled, the third test selection unit 230 generates the third test mode signal TM3 in response to the third select signal sel_{—}3.

When the control signal ctrl is enabled, the fourth test selection unit 240 generates the fourth test mode signal TM4 in response to the fourth select signal sel_{—}4.

When the control signal ctrl is enabled, the fifth test selection unit 250 generates the fifth test mode signal TM5 in response to the fifth select signal sel_{—}5. When the fifth test mode signal TM5 is enabled, the test reset signal generation unit 300 enables the test reset signal TM_reset. If the test reset signal TM_reset is enabled, the control signal generation unit 100 disables the control signal ctrl. When the control signal ctrl is disabled, the first to fifth test selection units 210 to 250 disable all of the first to fifth test mode signals TM1 to TM5.

In this way, in the semiconductor apparatus in accordance with an embodiment of the present invention, when performing a test, the first to fourth test mode signals TM1 to TM4 may be selectively enabled by enabling the control signal ctrl, and the test may be performed according to the first to fourth test mode signals TM1 to TM4 selectively enabled. Also, to end the test, the fifth select signal sel_{—}5 is enabled to enable the test reset signal TM_reset, and the control signal ctrl is disabled according to the enabled test reset signal TM_reset. The first to fifth test selection units 210 to 250 having received the disabled control signal ctrl disable all of the first to fifth test mode signals TM1 to TM5. Therefore, since all of the first to fourth test mode signals TM1 to TM4 are disabled, the test according to the first to fourth test mode signals TM1 to TM4 is not performed. Moreover, since the fifth test mode signal TM5 is disabled, the test reset signal generation unit 300 having received the disabled fifth test mode signal TM5 disables the test reset signal TM_reset. If the test reset signal TM_reset is disabled, the control signal generation unit 100 may enable again the control signal ctrl in response to the test signal Test and the set signal SET.

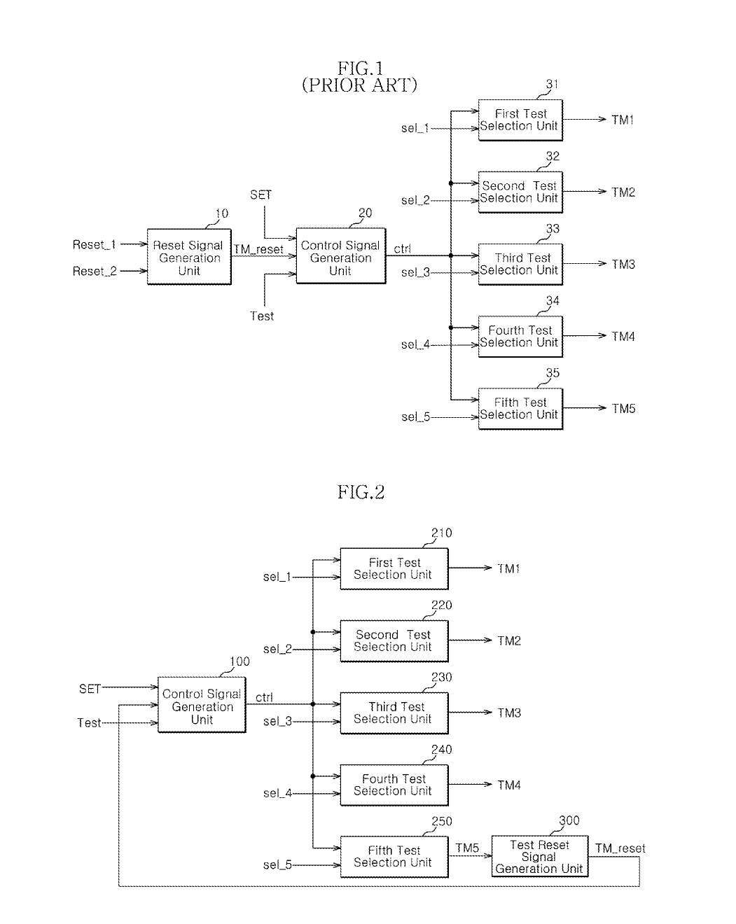

In an embodiment of the present invention, unlike the conventional semiconductor apparatus shown in FIG. 1, a plurality of test mode signals may be disabled using one select signal, and it is possible to enable the test mode signals in response to the select signal. Thus, without the need of inputting a reset signal as shown in FIG. 1 to selectively enable test mode signals all of which are disabled by another reset signal, a test may be both started and ended with the one select signal in the embodiment of the present invention.

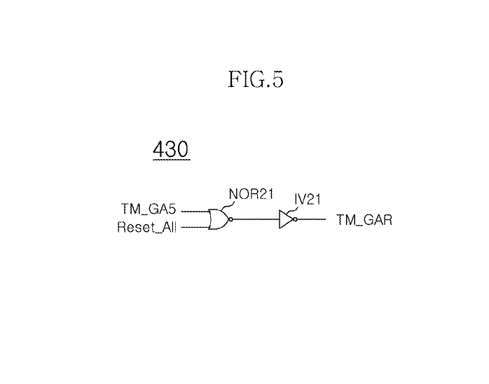

Referring to FIG. 4, a semiconductor apparatus in accordance with another embodiment of the present invention includes a first group test mode signal generation block 400, and a second group test mode signal generation block 500.

The first group test mode signal generation block 400 is configured to generate a plurality of first group test mode signals TM_GA1 to TM_GA5 in response to a set signal SET, a test signal Test and a plurality of first group select signals sel_GA1 to sel_GA5. Also, the first group test mode signal generation block 400 is configured to disable the plurality of first group test mode signals TM_GA1 to TM_GA5 in response to any one of the plurality of first group select signals sel_GA1 to sel_GA5. The plurality of first group select signals sel_GA1 to sel_GA5 include a first group first select signal sel_GA1, a first group second select signal sel_GA2, a first group third select signal sel_GA3, a first group fourth select signal sel_GA4, and a first group fifth select signal sel_GA5. The plurality of first group test mode signals TM_GA1 to TM_GA5 include a first group first test mode signal TM_GA1, a first group second test mode signal TM_GA2, a first group third test mode signal TM_GA3, a first group fourth test mode signal TM_GA4, and a first group fifth test mode signal TM_GA5.

For example, the first group test mode signal generation block 400 generates the first group first to fifth test mode signals TM_GA1 to TM_GA5 in response to the set signal SET, the test signal Test and the first group first to fifth select signals sel_GA1 to sel_GA5. Also, the first group test mode signal generation block 400 disables the first group first to fifth test mode signals TM_GA1 to TM_GA5 in response to the first group fifth select signal sel_GA5.

The first group test mode signal generation block 400 includes a first control signal generation unit 410, first to fifth test selection units 421 to 425, and a first group test reset signal generation unit 430.

The first control signal generation unit 410 is configured to generate a first group control signal ctrl_GA in response to the set signal SET, the test signal Test and a first group test reset signal TM_GAR. For example, the first control signal generation unit 410 enables the first group control signal ctrl_GA when the set signal SET and the test signal Test are enabled, and disables the first group control signal ctrl_GA when the first group test reset signal TM_GAR is enabled.

The first test selection unit 421 is configured to generate the first group first test mode signal TM_GA1 in response to the first group first select signal sel_GA1 when the first group control signal ctrl_GA is enabled. Moreover, the first test selection unit 421 is configured to disable the first group first test mode signal TM_GA1 regardless of the state of the first group first select signal sel_GA1 when the first group control signal ctrl_GA is disabled. Further, the first test selection unit 421 enables the first group first test mode signal TM_GA1 when the first group control signal ctrl_GA is enabled and the first group first select signal sel_GA1 is enabled, and disables the first group first test mode signal TM_GA1 when the first group control signal ctrl_GA is enabled and the first group first select signal sel_GA1 is disabled.

The second test selection unit 422 is configured to generate the first group second test mode signal TM_GA2 in response to the first group second select signal sel_GA2 when the first group control signal ctrl_GA is enabled. Moreover, the second test selection unit 422 is configured to disable the first group second test mode signal TM_GA2 regardless of the state of the first group second select signal sel_GA2 when the first group control signal ctrl_GA is disabled. Further, the second test selection unit 422 enables the first group second test mode signal TM_GA2 when the first group control signal ctrl_GA is enabled and the first group second select signal sel_GA2 is enabled, and disables the first group second test mode signal TM_GA2 when the first group control signal ctrl_GA is enabled and the first group second select signal sel_GA2 is disabled.

The third test selection unit 423 is configured to generate the first group third test mode signal TM_GA3 in response to the first group third select signal sel_GA3 when the first group control signal ctrl_GA is enabled. Moreover, the third test selection unit 423 is configured to disable the first group third test mode signal TM_GA3 regardless of the state of the first group third select signal sel_GA3 when the first group control signal ctrl_GA is disabled. Further, the third test selection unit 423 enables the first group third test mode signal TM_GA3 when the first group control signal ctrl_GA is enabled and the first group third select signal sel_GA3 is enabled, and disables the first group third test mode signal TM_GA3 when the first group control signal ctrl_GA is enabled and the first group third select signal sel_GA3 is disabled.

The fourth test selection unit 424 is configured to generate the first group fourth test mode signal TM_GA4 in response to the first group fourth select signal sel_GA4 when the first group control signal ctrl_GA is enabled. Moreover, the fourth test selection unit 424 is configured to disable the first group fourth test mode signal TM_GA4 regardless of the state of the first group fourth select signal sel_GA4 when the first group control signal ctrl_GA is disabled. Further, the fourth test selection unit 424 enables the first group fourth test mode signal TM_GA4 when the first group control signal ctrl_GA is enabled and the first group fourth select signal sel_GA4 is enabled, and disables the first group fourth test mode signal TM_GA4 when the first group control signal ctrl_GA is enabled and the first group fourth select signal sel_GA4 is disabled.

The fifth test selection unit 425 is configured to generate the first group fifth test mode signal TM_GA5 in response to the first group fifth select signal sel_GA5 when the first group control signal ctrl_GA is enabled. Moreover, the fifth test selection unit 425 is configured to disable the first group fifth test mode signal TM_GA5 regardless of the state of the first group fifth select signal sel_GA5 when the first group control signal ctrl_GA is disabled. Further, the fifth test selection unit 425 enables the first group fifth test mode signal TM_GA5 when the first group control signal ctrl_GA is enabled and the first group fifth select signal sel_GA5 is enabled, and disables the first group fifth test mode signal TM_GA5 when the first group control signal ctrl_GA is enabled and the first group fifth select signal sel_GA5 is disabled.

The first group test reset signal generation unit 430 is configured to generate the first group test reset signal TM_GAR in response to the first group fifth test mode signal TM_GA5 and a reset signal Reset_All. For example, the first group test reset signal generation unit 430 enables the first group test reset signal TM_GAR when any one of the first group fifth test mode signal TM_GA5 and the reset signal Reset_All is enabled.

The second group test mode signal generation block 500 is configured to generate a plurality of second group test mode signals TM_GB1 to TM_GB5 in response to the set signal SET, the test signal Test and a plurality of second group select signals sel_GB1 to sel_GB5. Also, the second group test mode signal generation block 500 is configured to disable the plurality of second group test mode signals TM_GB1 to TM_GB5 in response to any one of the plurality of second group select signals sel_GB1 to sel_GB5. The plurality of second group select signals sel_GB1 to sel_GB5 include a second group first select signal sel_GB1, a second group second select signal sel_GB2, a second group third select signal sel_GB3, a second group fourth select signal sel_GB4, and a second group fifth select signal sel_GB5. The plurality of second group test mode signals TM_GB1 to TM_GB5 include a second group first test mode signal TM_GB1, a second group second test mode signal TM_GB2, a second group third test mode signal TM_GB3, a second group fourth test mode signal TM_GB4, and a second group fifth test mode signal TM_GB5.

For example, the second group test mode signal generation block 500 generates the second group first to fifth test mode signals TM_GB1 to TM_GB5 in response to the set signal SET, the test signal Test and the second group first to fifth select signals sel_GB1 to sel_GB5. Also, the second group test mode signal generation block 500 disables the second group first to fifth test mode signals TM_GB1 to TM_GB5 in response to the second group fifth select signal sel_GB5.

The first and second group test mode signal generation blocks 400 and 500 disable the first group first to fifth test mode signals TM_GA1 to TM_GA5 and the second group first to fifth test mode signals TM_GB1 to TM_GB5 in response to the reset signal Reset_All.

The second group test mode signal generation block 500 includes a second control signal generation unit 510, sixth to tenth test selection units 521 to 525, and a second group test reset signal generation unit 530.

The second control signal generation unit 510 is configured to generate a second group control signal ctrl_GB in response to the set signal SET, the test signal Test and a second group test reset signal TM_GBR. For example, the second control signal generation unit 510 enables the second group control signal ctrl_GB when the set signal SET and the test signal Test are enabled, and disables the second group control signal ctrl_GB when the second group test reset signal TM_GBR is enabled.

The sixth test selection unit 521 is configured to generate the second group first test mode signal TM_GB1 in response to the second group first select signal sel_GB1 when the second group control signal ctrl_GB is enabled. Moreover, the sixth test selection unit 521 is configured to disable the second group first test mode signal TM_GB1 regardless of the state of the second group first select signal sel_GB1 when the second group control signal ctrl_GB is disabled. For example, the sixth test selection unit 521 enables the second group first test mode signal TM_GB1 when the second group control signal ctrl_GB is enabled and the second group first select signal sel_GB1 is enabled, and disables the second group first test mode signal TM_GB1 when the second group control signal ctrl_GB is enabled and the second group first select signal sel_GB1 is disabled.

The seventh test selection unit 522 is configured to generate the second group second test mode signal TM_GB2 in response to the second group second select signal sel_GB2 when the second group control signal ctrl_GB is enabled. Moreover, the seventh test selection unit 522 is configured to disable the second group second test mode signal TM_GB2 regardless of the state of the state of the second group second select signal sel_GB2 when the second group control signal ctrl_GB is disabled. Further, the seventh test selection unit 522 enables the second group second test mode signal TM_GB2 when the second group control signal ctrl_GB is enabled and the second group second select signal sel_GB2 is enabled, and disables the second group second test mode signal TM_GB2 when the second group control signal ctrl_GB is enabled and the second group second select signal sel_GB2 is disabled.

The eighth test selection unit 523 is configured to generate the second group third test mode signal TM_GB3 in response to the second group third select signal sel_GB3 when the second group control signal ctrl_GB is enabled. Moreover, the eighth test selection unit 523 is configured to disable the second group third test mode signal TM_GB3 regardless of the state of the second group third select signal sel_GB3 when the second group control signal ctrl_GB is disabled. Further, the eighth test selection unit 523 enables the second group third test mode signal TM_GB3 when the second group control signal ctrl_GB is enabled and the second group third select signal sel_GB3 is enabled, and disables the second group third test mode signal TM_GB3 when the second group control signal ctrl_GB is enabled and the second group third select signal sel_GB3 is disabled.

The ninth test selection unit 524 is configured to generate the second group fourth test mode signal TM_GB4 in response to the second group fourth select signal sel_GB4 when the second group control signal ctrl_GB is enabled. Moreover, the ninth test selection unit 524 is configured to disable the second group fourth test mode signal TM_GB4 regardless of the state of the second group fourth select signal sel_GB4 when the second group control signal ctrl_GB is disabled. Further, the ninth test selection unit 524 enables the second group fourth test mode signal TM_GB4 when the second group control signal ctrl_GB is enabled and the second group fourth select signal sel_GB4 is enabled, and disables the second group fourth test mode signal TM_GB4 when the second group control signal ctrl_GB is enabled and the second group fourth select signal sel_GB4 is disabled.

The tenth test selection unit 525 is configured to generate the second group fifth test mode signal TM_GB5 in response to the second group fifth select signal sel_GB5 when the second group control signal ctrl_GB is enabled. Moreover, the tenth test selection unit 525 is configured to disable the second group fifth test mode signal TM_GB5 regardless of the state of the second group fifth select signal sel_GB5 when the second group control signal ctrl_GB is disabled. Further, the tenth test selection unit 525 enables the second group fifth test mode signal TM_GB5 when the second group control signal ctrl_GB is enabled and the second group fifth select signal sel_GB5 is enabled, and disables the second group fifth test mode signal TM_GB5 when the second group control signal ctrl_GB is enabled and the second group fifth select signal sel_GB5 is disabled.

The second group test reset signal generation unit 530 is configured to generate the second group test reset signal TM_GBR in response to the second group fifth test mode signal TM_GB5 and the reset signal Reset_All. Further, the second group test reset signal generation unit 530 enables the second group test reset signal TM_GBR when any one of the second group fifth test mode signal TM_GB5 and the reset signal Reset_All is enabled.

Since the first group test reset signal generation unit 430 and the second group test reset signal generation unit 530 have the substantially same configuration except that the names of the signals inputted thereto and outputted therefrom are different from each other, only the configuration of the first group test reset signal generation unit 430 will be described.

Referring to FIG. 5, the first group test reset signal generation unit 430 includes a NOR gate NOR21 and a third inverter IV21. The NOR gate NOR21 receives the first group fifth test mode signal TM_GA5 and the reset signal Reset_All. The third inverter IV21 receives the output signal of the NOR gate NOR21 and outputs the first group test reset signal TM_GAR.

Operations of the semiconductor apparatus in accordance with another embodiment of the present invention, configured as mentioned above, will be described below.

When the test signal Test and the set signal SET are enabled, the first group test mode signal generation block 400 selectively enables the first group first to fifth test mode signals TM_GA1 to TM_GA5 in response to the first group first to fifth select signals sel_GA1 to sel_GA5.

Further, when the test signal Test and the set signal SET are enabled, the second group test mode signal generation block 500 selectively enables the second group first to fifth test mode signals TM_GB1 to TM_GB5 in response to the second group first to fifth select signals sel_GB1 to sel_GB5.

Therefore, if the test signal Test and the set signal SET are enabled, the semiconductor apparatus may perform tests according to the first group first to fourth test mode signals TM_GA1 to TM_GA4 and the second group first to fourth test mode signals TM_GB1 to TM_GB4.

When it is necessary to end the test according to the first group first to fourth test mode signals TM_GA1 to TM_GA4, the first group fifth select signal sel_GA5 is enabled. Accordingly, the first group fifth test mode signal TM_GA5 is enabled, and the first group test reset signal RM_GAR is enabled. If the first group test reset signal TM_GAR is enabled, the first control signal generation unit 410 disables the first group control signal ctrl_GA. Thus, the first group first to fourth test mode signals TM_GA1 to TM_GA4, which have been selectively enabled, and the first group fifth test mode signal TM_GA5, which has enabled the first group test reset signal TM_GAR, are all disabled.

As a consequence, as the first group first to fourth test mode signals TM_GA1 to TM_GA4 are disabled, the test according to the first group first to fourth test mode signals TM_GA1 to TM_GA4 is ended.

Also, when it is necessary to end the test according to the second group first to fourth test mode signals TM_GB1 to TM_GB4, the second group fifth select signal sel_GB5 is enabled. According to this fact, the second group fifth test mode signal TM_GB5 is enabled, and the second group test reset signal RM_GBR is enabled. If the second group test reset signal TM_GBR is enabled, the second control signal generation unit 510 disables the second group control signal ctrl_GB. Thus, the second group first to fourth test mode signals TM_GB1 to TM_GB4, which have been selectively enabled, and the second group fifth test mode signal TM_GB5, which has enabled the second group test reset signal TM_GBR, are all disabled.

As a consequence, as the second group first to fourth test mode signals TM_GB1 to TM_GB4 are disabled, the test according to the second group first to fourth test mode signals TM_GB1 to TM_GB4 is ended.

When it is necessary to simultaneously end the test according to the first group first to fourth test mode signals TM_GA1 to TM_GA4 and the test according to the second group first to fourth test mode signals TM_GB1 to TM_GB4, the reset signal Reset_All is enabled.

If the reset signal Reset_All is enabled, both the first group test reset signal TM_GAR and the second group test reset signal TM_GBR are enabled, and accordingly, both the first group control signal ctrl_GA and the second group control signal ctrl_GB are disabled. If the first and second group control signal ctrl_GA and ctrl_GB are disabled, the first group first to fourth test mode signals TM_GA1 to TM_GA4 and the second group first to fourth test mode signals TM_GB1 to TM_GB4 are all disabled, and accordingly, the tests according to the first group first to fourth test mode signals TM_GA1 to TM_GA4 and the second group first to fourth test mode signals TM_GB1 to TM_GB4 are all ended.

In this way, in the semiconductor apparatus in accordance with another embodiment of the present invention, the tests according to the first group first to fourth test mode signals TM_GA1 to TM_GA4 and the second group first to fourth test mode signals TM_GB1 to TM_GB4 may be selectively or simultaneously ended without separate signal input.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising:
a control signal generation unit configured to generate a control signal in response to a set signal, a test signal and a test reset signal;
a first test selection unit configured to generate a first test mode signal in response to a first select signal and the control signal;
a second test selection unit configured to generate a second test mode signal in response to a second select signal and the control signal; and
a test reset signal generation unit configured to output the second test mode signal as the test reset signal.

2. The semiconductor apparatus according to claim 1, wherein the control signal generation unit enables the control signal when the test signal and the set signal are enabled, and disables the control signal when the test reset signal is enabled.

3. The semiconductor apparatus according to claim 2, wherein the first test selection unit generates the first test mode signal in response to the first select signal when the control signal is enabled, and disables the first test mode signal regardless of the state of the first select signal when the control signal is disabled.

4. The semiconductor apparatus according to claim 2, wherein the first test selection unit enables the first test mode signal when the control signal is enabled and the first select signal is enabled, and disables the first test mode signal when the control signal is enabled and the first select signal is disabled.

5. The semiconductor apparatus according to claim 2, wherein the second test selection unit generates the second test mode signal in response to the second select signal when the control signal is enabled, and disables the second test mode signal regardless of the state of the second select signal when the control signal is disabled.

6. The semiconductor apparatus according to claim 5, wherein the second test selection unit enables the second test mode signal when the control signal is enabled and the second select signal is enabled, and disables the second test mode signal when the control signal is enabled and the second select signal is disabled.

7. The semiconductor apparatus according to claim 6, wherein the test reset signal generation unit enables the test reset signal when the second test mode signal is enabled, and disables the test reset signal when the second test mode signal is disabled.

8. A semiconductor apparatus comprising:
a first group test mode signal generation block configured to generate a plurality of first group test mode signals in response to a set signal, a test signal and a plurality of first group select signals, and disable the plurality of first group test mode signals in response to any one of the plurality of first group select signals; and
a second group test mode signal generation block configured to generate a plurality of second group test mode signals in response to the set signal, the test signal and a plurality of second group select signals, and disable the plurality of second group test mode signals in response to any one of the plurality of second group select signals.

9. The semiconductor apparatus according to claim 8, wherein the first and second group test mode signal generation blocks disable the plurality of first group test mode signals and the plurality of second group test mode signals in response to a reset signal.

10. The semiconductor apparatus according to claim 9,
wherein the plurality of first group select signals comprise a first group first select signal and a first group second select signal,
wherein the plurality of first group test mode signals comprise a first group first test mode signal and a first group second test mode signal, and
wherein the first group test mode signal generation block comprises:
a first control signal generation unit configured to generate a first group control signal in response to the set signal, the test signal and a first group test reset signal;
a first test selection unit configured to generate the first group first test mode signal in response to the first group first select signal when the first group control signal is enabled;
a second test selection unit configured to generate the first group second test mode signal in response to the first group second select signal when the first group control signal is enabled; and
a first group test reset signal generation unit configured to generate the first group test reset signal in response to the first group second test mode signal and the reset signal.

11. The semiconductor apparatus according to claim 10, wherein the first control signal generation unit enables the first group control signal when the set signal and the test signal are enabled, and disables the first group control signal when the first group test reset signal is enabled.

12. The semiconductor apparatus according to claim 11, wherein the first test selection unit enables the first group first test mode signal when the first group control signal is enabled and the first group first select signal is enabled, disables the first group first test mode signal when the first group control signal is enabled and the first group first select signal is disabled, and disables the first group first test mode signal regardless of the state of the first group first select signal when the first group control signal is disabled.

13. The semiconductor apparatus according to claim 11, wherein the second test selection unit enables the first group second test mode signal when the first group control signal is enabled and the first group second select signal is enabled, disables the first group second test mode signal when the first group control signal is enabled and the first group second select signal is disabled, and disables the first group second test mode signal regardless of the state of the first group second select signal when the first group control signal is disabled.

14. The semiconductor apparatus according to claim 11, wherein the first group test reset signal generation unit enables the first group test reset signal when any one of the first group second test mode signal and the reset signal is enabled.

15. The semiconductor apparatus according to claim 9,
wherein the plurality of second group select signals comprise a second group first select signal and a second group second select signal,
wherein the plurality of second group test mode signals comprise a second group first test mode signal and a second group second test mode signal, and
wherein the second group test mode signal generation block comprises:
a second control signal generation unit configured to generate a second group control signal in response to the set signal, the test signal and a second group test reset signal;
a first test selection unit configured to generate the second group first test mode signal in response to the second group first select signal when the second group control signal is enabled;
a second test selection unit configured to generate the second group second test mode signal in response to the second group second select signal when the second group control signal is enabled; and
a second group test reset signal generation unit configured to generate the second group test reset signal in response to the second group second test mode signal and the reset signal.

16. The semiconductor apparatus according to claim 15, wherein the second control signal generation unit enables the second group control signal when the set signal and the test signal are enabled, and disables the second group control signal when the second group test reset signal is enabled.

17. The semiconductor apparatus according to claim 16, wherein the first test selection unit enables the second group first test mode signal when the second group control signal is enabled and the second group first select signal is enabled, disables the second group first test mode signal when the second group control signal is enabled and the second group first select signal is disabled, and disables the second group first test mode signal regardless of the state of the second group first select signal when the second group control signal is disabled.

18. The semiconductor apparatus according to claim 17, wherein the second test selection unit enables the second group second test mode signal when the second group control signal is enabled and the second group second select signal is enabled, disables the second group second test mode signal when the second group control signal is enabled and the second group second select signal is disabled, and disables the second group second test mode signal regardless of the state of the second group second select signal when the second group control signal is disabled.

19. The semiconductor apparatus according to claim 18, wherein the second group test reset signal generation unit enables the second group test reset signal when any one of the second group second test mode signal and the reset signal is enabled.
